(19) United States
(12) Patent Application Publication
(10) Pub. No.: US 2015/0332942 A1
(43) Pub. Date: Nov. 19, 2015

(54) PEDESTAL FLUID-BASED THERMAL CONTROL

(71) Applicants: Eng Sheng Peh, Singapore (SG); Sriskantharajah Thirunavukarasu, Singapore (SG); Karthik Elumalai, Bangalore (IN); Kirankumar Savandaiah, Bangalore (IN)

(72) Inventors: Eng Sheng Peh, Singapore (SG); Sriskantharajah Thirunavukarasu, Singapore (SG); Karthik Elumalai, Bangalore (IN); Kirankumar Savandaiah, Bangalore (IN)

(21) Appl. No.: 14/280,031

(22) Filed: May 16, 2014

(51) Int. Cl. H01L 21/67; H01L 21/687

(52) U.S. Cl. CPC H01L 21/67109; H01L 21/687

(57) ABSTRACT

Thermal control of substrate carrier is described using a thermal fluid. In one example, a thermally controlled substrate support includes a top surface to support a substrate, the top surface being thermally coupled to substrate, a thermal fluid channel thermally coupled to the top surface to carry a thermal fluid, the thermal fluid to draw heat from and provide heat to the top surface, and a heat exchanger to supply thermal fluid to the thermal fluid channel, the heat exchanger alternately heating and cooling the thermal fluid to adjust the substrate temperature.

### FIELD

Embodiments of the present invention relate to the microelectronics manufacturing industry and more particularly to temperature controlled pedestals for supporting a workpiece during processing.

### BACKGROUND

In the manufacture of semiconductor chips, a silicon wafer or other substrate is exposed to a variety of different processes in different processing chambers. The chambers may expose the wafer to a number of different chemical and physical processes whereby minute integrated circuits are created on the substrate. Layers of materials which make up the integrated circuit are created by processes including chemical vapor deposition, physical vapor deposition, epitaxial growth, and the like. Some of the layers of material are patterned using photoresist masks and wet or dry etching techniques. The substrates may be silicon, gallium arsenide, indium phosphide, glass, or other appropriate materials.

In these manufacturing processes, plasma may be used for depositing or etching various material layers. Plasma processing offers many advantages over the final processing. For example, plasma enhanced chemical vapor deposition (PECVD) allows deposition processes to be performed at lower temperatures and at higher deposition rates than in analogous thermal processes. PECVD therefore allows material to be deposited at lower temperatures.

The processing chambers used in these processes typically include a substrate support or pedestal disposed therein to support the substrate during processing. In some processes, the pedestal may include an embedded heater adapted to control the temperature of the substrate and/or provide elevated temperatures that may be used in the process.

As fabrication techniques advance, the temperature of the wafer during processing becomes more important. Some pedestals have been designed for thermal uniformity across the surface of the substrate, sometimes called a workpiece. Liquid cooling is used to absorb the plasma power heat and remove it from the workpiece. A pedestal may also include independently controlled heaters in multiple zones. This allows for a wider process window under different processes such as chemical vapor and plasma conditions.

For many processes, the temperature of a wafer during processing influences the rate at which structures on the wafer are formed, exposed, developed, or etched. Other processes may also have a temperature dependence. A more precise thermal performance allows for more precisely formed structures on the wafer. Uniform etch rates across the wafer allow smaller structures to be formed on the wafer. Thermal performance or temperature control is therefore a factor in reducing the size of transistors and other structures on a silicon chip.

### SUMMARY

Thermal control of substrate carrier is described using a thermal fluid. In one example, a thermally controlled substrate support includes a top surface to support a substrate, the top surface being thermally coupled to substrate, a thermal fluid channel thermally coupled to the top surface to carry a thermal fluid, the thermal fluid to draw heat from and provide heat to the top surface, and a heat exchanger to supply thermal fluid to the thermal fluid channel, the heat exchanger alternately heating and cooling the thermal fluid to adjust the substrate temperature.

### BRIEF DESCRIPTION OF THE DRAWINGS

Embodiments of the present invention are illustrated by way of example, and not limitation, in the figures of the accompanying drawings in which:

FIG. 1 is a schematic diagram of a semiconductor processing system including a pedestal assembly in accordance with an embodiment of the present invention;

FIG. 2 is an isometric diagram of a pedestal assembly according to an embodiment of the present invention;

FIG. 3 is a cross-sectional diagram of the pedestal assembly of FIG. 2 according to an embodiment of the present invention;

FIG. 4 is a top plan view diagram of a cooling plate of the pedestal assembly of FIG. 2 according to an embodiment of the present invention;

FIG. 5 is an isometric diagram of the pedestal assembly of FIG. 2 according to an embodiment of the present invention;

FIG. 6 is a partial cross-sectional diagram of portions of the top surface of the pedestal assembly of FIG. 2 according to an embodiment of the present invention;

FIG. 7 is a cross-sectional side view diagram of a gas plug installed in the pedestal assembly of FIG. 2 according to an embodiment of the present invention;

FIG. 8 is a top plan view diagram of the gas plug of FIG. 7 according to an embodiment of the present invention;

FIG. 9 is a process flow diagram of operating a processing chamber with a substrate support assembly according to an embodiment of the present invention; and

FIG. 10 is a cross-sectional diagram of a substrate support assembly in the form of an electrostatic chuck according to an embodiment of the present invention.

### DETAILED DESCRIPTION

In the following description, numerous details are set forth, however, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” my be used to indicate that two or more elements are in either direct or indirect (with other intervening elements between them) physical, optical, or electrical contact with each other, and/or that the two or more elements co-operate or interact with each other (e.g., as in a cause an effect relationship).

The terms “over,” “under,” “between,” and “on” as used herein refer to a relative position of one component or material layer with respect to other components or layers where such physical relationships are noteworthy. For example in the context of material layers, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similar distinctions are to be made in the context of component assemblies.

The temperature of a top surface of a wafer pedestal and, as a result, the temperature of a wafer may be more precisely controlled during processing by using the coolant fluid also as a heating fluid. The same fluid used to remove excess heat may also be used to provide additional heat. The temperature of the coolant fluid may be precisely controlled using a heat exchanger that is outside the chamber.

If resistive heating elements are no longer used, then the heater structures can be removed from the pedestal assembly. This allows the pedestal to be made thinner. The reduced thickness of the pedestal allows the coolant fluid to thermally couple more effectively to the wafer. The other heater components, such as a PID (Proportional-Integral-Derivative) temperature controller sensor, control system, and electrical connectors are also avoided when the resistive heater traces are removed.

Instead, the external heat exchanger may be used to increase or decrease the temperature of the coolant. The temperature of the coolant may be measured and used as an indication of the temperature of the pedestal and of the wafer as the coolant flows from the pedestal. Additional sensors, such as thermocouples, may be used in addition to or instead of the coolant temperature. For many processes, it is sufficient for the heat exchanger to control the coolant temperature within a range of between 30° C. to 200° C.

Gas may be delivered to the back side of the wafer between the top surface of the pedestal and the wafer to improve heat convection between the wafer and the pedestal. An effective radial gas flow improves gas flow across the back side of the wafer. The gas may be pumped through a channel in the base of the pedestal assembly to the top of the pedestal. A mass flow controller may be used to control the flow through the pedestal. In a vacuum or chemical deposition chamber, the backside gas provides a medium for heat transfer for heating and cooling of the wafer during processing. Gas flow may be improved by establishing a radial flow pattern from the center of the wafer in stepped pockets in the heater pedestal design.

Heat transfer may also be improved using bumps between the pedestal and the wafer that contact the back side of the wafer. The surface diameter and number of bumps may be increased for increased heat conduction through the bumps.

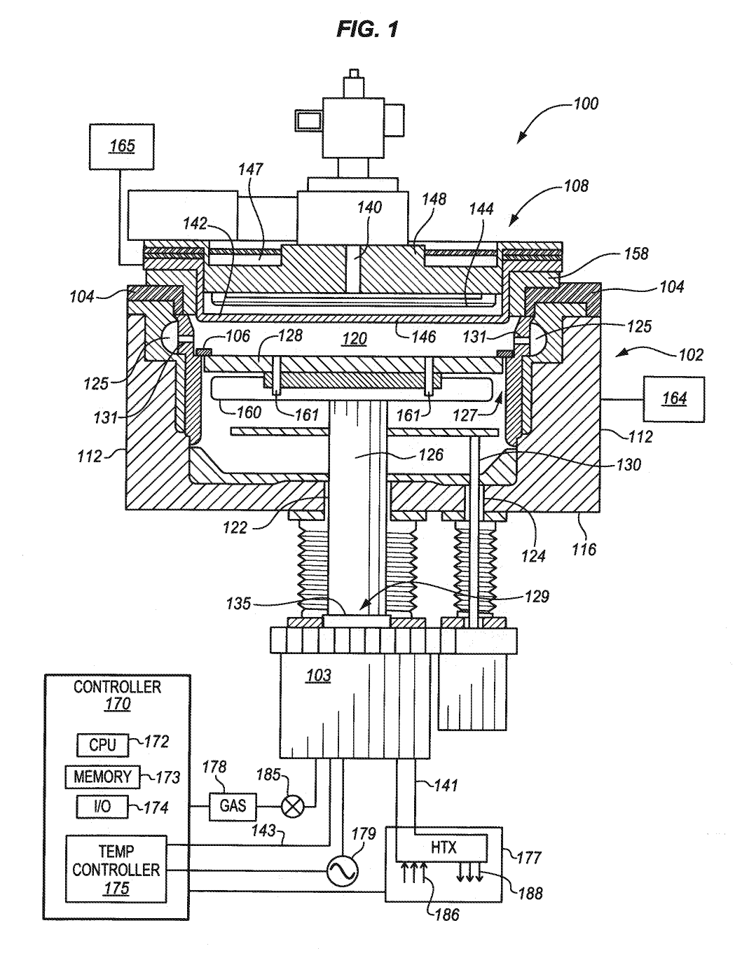

FIG. 1 is a partial cross sectional view of a plasma system 100 having a pedestal 128 according to embodiments described herein. The pedestal 128 has an active cooling system which allows for active control of the temperature of a substrate positioned on the pedestal over a wide temperature range while the substrate is subjected to numerous process and chamber conditions. The plasma system 100 includes a processing chamber body 102 having sidewalls 112 and a bottom wall 116 defining a processing region 120.

A pedestal 128 is disposed in the processing region 120 through a passage 122 formed in the bottom wall 116 in the system 100. The pedestal 128 is adapted to support a substrate (not shown) on its upper surface. The substrate may be any of a variety of different workpieces for the processing applied by the chamber 100 made of any of a variety of different materials. The pedestal 128 may optionally include heating elements (not shown), for example resistive elements, to heat and control the substrate temperature at a desired process temperature. Alternatively, the pedestal 128 may be heated by a remote heating element, such as a lamp assembly.

The pedestal 128 is coupled by a shaft 126 to a power outlet or power box 103, which may include a drive system that controls the elevation and movement of the pedestal 128 within the processing region 120. The shaft 126 also contains electrical power interfaces to provide electrical power to the pedestal 128. The power box 103 also includes interfaces for electrical power and temperature indicators, such as a thermocouple interface. The shaft 126 also includes a base assembly 129 adapted to detachably couple to the power box 103. A circumferential ring 135 is shown above the power box 103. In one embodiment, the circumferential ring 135 is a shoulder adapted as a mechanical stop or land configured to provide a mechanical interface between the base assembly 129 and the upper surface of the power box 103.

A rod 130 is disposed through a passage 124 formed in the bottom wall 116 and is used to activate substrate lift pins 161 disposed through the pedestal 128. The substrate lift pins 161 lift the workpiece off the pedestal top surface to allow the workpiece to be removed and taken in and out of the chamber, typically using a robot (not shown) through a substrate transfer port 160.

A chamber lid 104 is coupled to a top portion of the chamber body 102. The lid 104 accommodates one or more gas distribution systems 108 coupled thereto. The gas distribution system 108 includes a gas inlet passage 140 which delivers reactant and cleaning gases through a showerhead assembly 142 into the processing region 120B. The showerhead assembly 142 includes an annular base plate 148 having a blocker plate 144 disposed intermediate to a faceplate 146.

A radio frequency (RF) source 165 is coupled to the showerhead assembly 142. The RF source 165 powers the showerhead assembly 142 to facilitate generation of plasma between the faceplate 146 of the showerhead assembly 142 and the heated pedestal 128. In one embodiment, the RF source 165 may be a high frequency radio frequency (HFRF) power source, such as a 13.56 MHz RF generator. In another embodiment, RF source 165 may include a HFRF power source and a low frequency radio frequency (LFRF) power source, such as a 300 kHz RF generator. Alternatively, the RF source may be coupled to other portions of the processing chamber body 102, such as the pedestal 128, to facilitate plasma generation. A dielectric isolator 158 is disposed between the lid 104 and showerhead assembly 142 to prevent conducting RF power to the lid 104. A shadow ring 106 may be disposed on the periphery of the pedestal 128 that engages the substrate at a desired elevation of the pedestal 128.

Optionally, a cooling channel 147 is formed in the annular base plate 148 of the gas distribution system 108 to cool the annular base plate 148 during operation. A heat transfer fluid, such as water, ethylene glycol, a gas, or the like, may be circulated through the cooling channel 147 such that the base plate 148 is maintained at a predefined temperature.

A chamber liner assembly 127 is disposed within the processing region 120 in very close proximity to the sidewalls 101, 112 of the chamber body 102 to prevent exposure of the sidewalls 101, 112 to the processing environment within the processing region 120. The liner assembly 127 includes a circumferential pumping cavity 125 that is coupled to a pumping system 164 configured to exhaust gases and byproducts from the processing region 120 and control the pressure within the processing region 120. A plurality of exhaust ports 131 may be formed on the chamber liner assembly 127. The exhaust ports 131 are configured to allow the flow of gases from the processing region 120 to the circumferential pumping cavity 125 in a manner that promotes processing within the system 100.

A system controller 170 is coupled to a variety of different systems to control a fabrication process in the chamber. The controller 170 may include a temperature controller 175 to execute temperature control algorithms (e.g., temperature feedback control) and may be either software or hardware or a combination of both software and hardware. The system controller 170 also includes a central processing unit 172, memory 173 and input/output interface 174. The temperature controller receives a temperature reading 143 from a sensor (not shown) on the pedestal. The temperature sensor may be proximate a coolant channel, proximate the wafer, or placed in the dielectric material of the pedestal. The temperature controller 175 uses the sensed temperature or temperatures to output control signals affecting the rate of heat transfer between the pedestal assembly 142 and a heat source and/or heat sink external to the plasma chamber 105, such as a heat exchanger 177.

The system may also include a controlled heat transfer fluid loop 141 with flow controlled based on the temperature feedback loop. In the example embodiment, the temperature controller 175 is coupled to a heat exchanger (HTX)/chiller 177. Heat transfer fluid flows through a valve (not shown) at a rate controlled by the valve through the heat transfer fluid loop 141. The valve may be incorporate into the heat exchanger or into a pump inside or outside of the heat exchanger to control the flow rate of the thermal fluid. The heat transfer fluid flows through conduits in the pedestal assembly 142 and then returns to the HTX 177. The temperature of the heat transfer fluid is increased or decreased by the HTX and then the fluid is returned through the loop back to the pedestal assembly.

The HTX includes a heater 186 to heat the heat transfer fluid and thereby heat the substrate. The heater may be formed using resistive coils around a pipe within the heat exchanger or with a heat exchanger in which a heated fluid conducts heat through an exchanger to a conduit containing the thermal fluid. The HTX also includes a cooler 188 which draws heat from the thermal fluid. This may be done using a radiator to dump heat into the ambient air or into a coolant fluid or in any of a variety of other ways. The heater and the cooler may be combined so that a temperature controlled fluid is first heated or cooled and then the heat of the control fluid is exchanged with that of the thermal fluid in the heat transfer fluid loop.

The valve (or other flow control devices) between the HTX 177 and fluid conduits in the pedestal assembly 142 may be controlled by the temperature controller 175 to control a rate of flow of the heat transfer fluid to the fluid loop. The temperature controller 175, the temperature sensor, and the valve may be combined in order to simplify construction and operation. In embodiments, the heat exchanger senses the temperature of the heat transfer fluid after it returns from the fluid conduit and either heats or cools the heat transfer fluid based on the temperature of the fluid and the desired temperature for the operational state of the chamber 102.

Electric heaters (not shown) may also be used in the pedestal assembly to apply heat to the pedestal assembly. The electric heaters, typically in the form of resistive elements are coupled to a power supply 179 that is controlled by the temperature control system 175 to energize the heater elements to obtain a desired temperature.

The heat transfer fluid may be a liquid, such as, but not limited to deionized water/ethylene glycol, a fluorinated coolant such as Fluorinert® from 3M or Galden® from Solvay Solexis, Inc. or any other suitable dielectric fluid such as those containing perfluorinated inert polyethers. While the present description describes the pedestal in the context of a PECVD processing chamber, the pedestal described herein may be used in a variety of different chambers and for a variety of different processes.

A backside gas source 178 such as a pressurized gas supply or a pump and gas reservoir are coupled to the chuck assembly 142 through a mass flow meter 185 or other type of valve. The backside gas may be argon or any gas that provides heat convection between the wafer and the puck without affecting the processes of the chamber. The gas source pumps gas through a gas outlet of the pedestal assembly described in more detail below to the back side of the wafer under the control of the system controller 170 to which the system is connected.

The processing system 100 may also include other systems, not specifically shown in FIG. 1, such as plasma sources, vacuum pump systems, access doors, micromachining, laser systems, and automated handling systems, inter alia. The illustrated chamber is provided as an example and any of a variety of other chambers may be used with the present invention, depending on the nature of the workpiece and desired processes. The described pedestal and thermal fluid control system may be adapted for use with different physical chambers and processes.

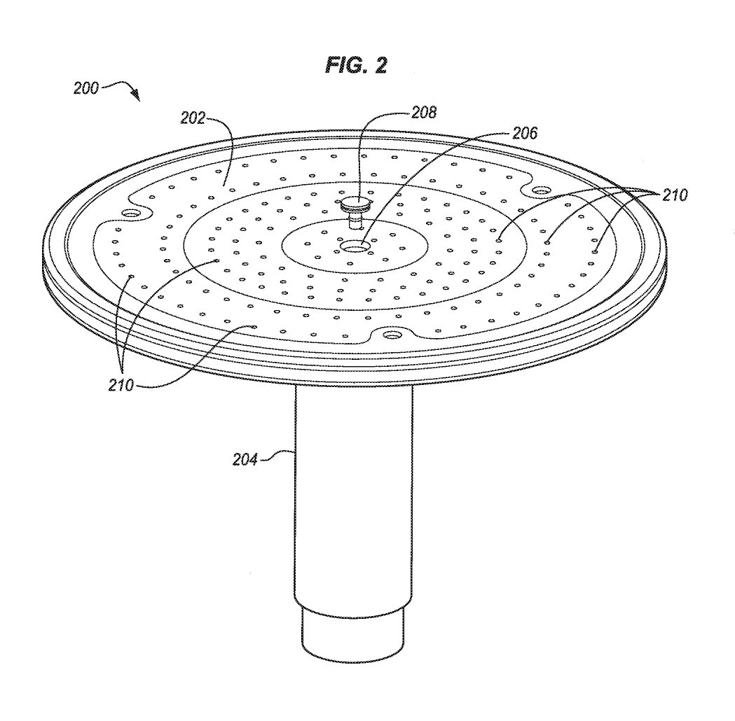

FIG. 2 is an isometric diagram of a substrate supports assembly in the form of a wafer pedestal 200 in accordance with an embodiment. The pedestal or cathode has a top dielectric surface 202 and a support shaft 204. The top dielectric surface may be formed using a cast and machined aluminum plate that is then coated with a dielectric such as aluminum nitride, aluminum oxide, or another oxide or ceramic material. Alternatively, the top surface may be formed entirely from an oxide, ceramic, or other dielectric material. This top plate that includes the dielectric top surface of the wafer pedestal will be referred to herein as a puck. A gas outlet 206 is bored through the center of the dielectric puck 202. A gas plug 208 is inserted into the center of the gas outlet channel 206 to control the flow of gas from the support column 204 out through the gas outlet 206 to the top surface of the dielectric puck 202.

The top surface of the dielectric puck has a plurality of bumps 210 so that a wafer or any other substrate resting on the top of the dielectric puck will be supported by the array of small bumps. The small bumps may be formed on the surface of the dielectric puck or the bumps may be attached. The bumps hold the wafer away from the top surface of the puck. The position of the wafer is determined by the height of each bump.

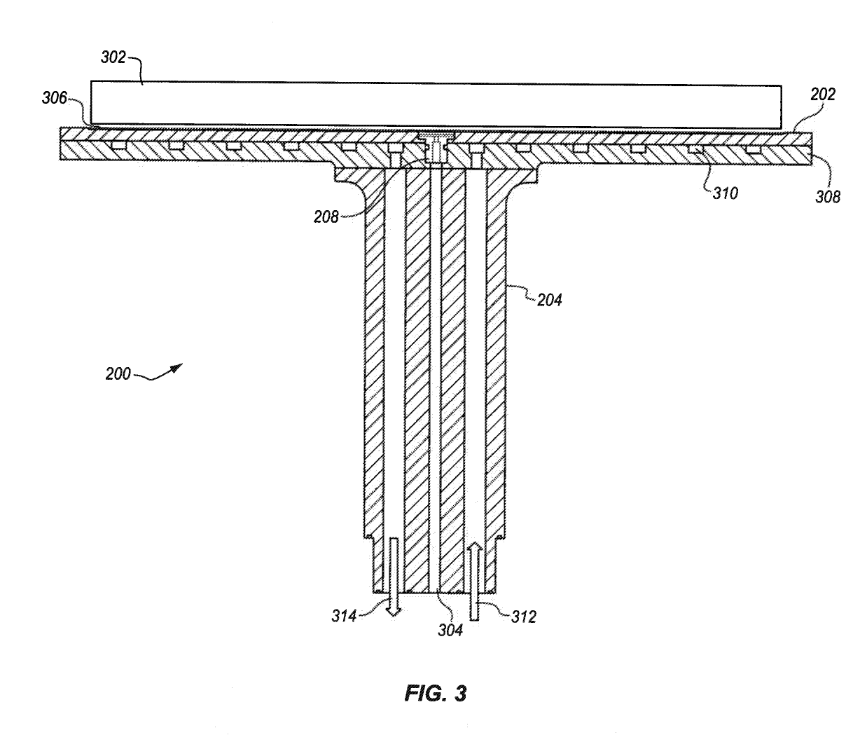

FIG. 3 is a cross-sectional side view diagram of the pedestal assembly 200 of FIG. 2. As shown in FIG. 3 the base 204 of the pedestal assembly has a central gas tube 304 which receives a thermally-conductive gas from an external source, such as the gas source 178 of FIG. 1. The gas is pumped up through a tube in the center of the pedestal support to a gas plug 208. From the gas plug, it exits from the pedestal to a space 306 between the dielectric puck 202 and a wafer 302 over the dielectric puck.

The pedestal assembly is formed of three separate major parts, although the invention is not so limited. There is an upper disk shaped structure 202 formed by the dielectric puck which has about the same surface area as the wafer 302. In the illustrated example, the wafer has a diameter of, for example, about 300 mm. The puck, accordingly, has a diameter of, for example, about 330 mm. The workpiece and the puck may be other shapes including rectangular and be of any desired size. The puck may be made of a ceramic or other rigid material with low electrical conductivity. Aluminum oxide and aluminum nitride are suitable materials, among others. While high thermal conductivity is an advantage in some applications, heat conduction may also be enhanced by making the puck very thin.

There is a lower heater plate 308 that is attached to the puck and a support shaft 204 attached to the heater plate. The heater plate and the support shaft may be made of strong metal with high thermal conductivity, such as aluminum or of other materials. The dielectric puck is attached to the heater plate using a welding process adhesive or another fastener, such as bolts or screws (not shown).

The heater plate has a pattern of coolant channels 310. In the illustrated example the coolant channels are machined into the lower heater plate as grooves which are open on the top surface of the heater plate. The coolant channels are closed by attaching the top dielectric puck 202 over the tops of the coolant channels. This design in which the puck forms the top surface of the coolant channels allows the heat transfer fluid to contact the puck directly, improving thermal conduction between the puck and the heat transfer fluid. The coolant channels have an inlet 312 where coolant fluid flows from a heat exchanger through the base of the pedestal 204 up into the coolant channels. The coolant flows through the channel and arrives at a coolant outlet 314 where it is pushed by the incoming coolant out the outlet back to the heat exchanger. A heat exchanger 177, such as that shown in FIG. 1, may supply the heat transfer fluid at a particular controlled temperature to one or more pedestals in various chambers.

By controlling the temperature of the heat transfer fluid, the temperature of the wafer can be controlled. The heat transfer fluid is in direct physical contact with the heater plate 308 and with the puck. The heater plate is also thermally coupled to the upper dielectric puck 202 which supports the wafer 302. The gas channel 304 applies a gas to the space between the wafer and the dielectric puck. This gas is a heat conduction medium that allows heat to be conducted between the wafer and the dielectric puck even if the chamber is a vacuum chamber. In this way, the temperature of the wafer may be controlled by controlling the temperature of the heat transfer fluid in the coolant channels.

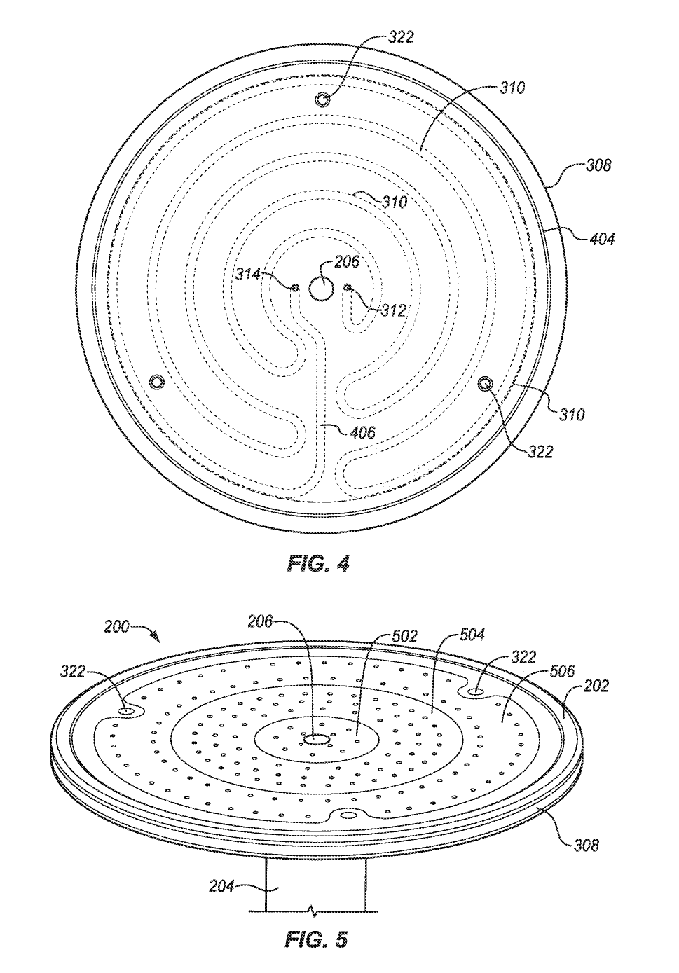

FIG. 4 is a top plan view of the pedestal assembly 200 with the dielectric puck 202 removed showing the top of the heater plate 308. As shown, the coolant inlet 312 provides heat transfer fluid into the open coolant channel 310 which circles the coolant heater plate in a circular pattern starting near the center of the puck near the gas outlet 206 and moving around the center toward the outside in a series of concentric arcs each arc being closer to the perimeter 404 of the puck. A return channel 406 runs radially from the perimeter back toward the center of the puck and to the coolant outlet 314.

The path followed by the coolant channels may be modified to suit different applications, construction materials, flow requirements, and heat transfer requirements. As shown each arc is almost a full circle and each arc is farther from the center than the arc before it. The arcs may be made shorter to cover only one half, one third, or another fraction of the full circle. The arcs may also be connected in a different order so that an inner arc is followed by an outer arc which is followed by another inner arc.

While a circular pattern is shown, a spiral pattern, a radial pattern, or any other pattern may alternatively be used. The path may be modified so that coolant is applied and removed from different locations or multiple locations on the heater plate. The central entry and exit allow the coolant channels to easily be supplied by the stand 204, however, if the coolant is supplied to the heater plate in another way then the entry and exit may be placed closer to the edge or to the periphery of the heater plate.

The hole 206 for gas flow is also shown in the center of the heater plate. This hole couples to a hole in the dielectric puck to which the gas plug is inserted.

FIG. 5 is an enlarged isometric view of the top surface of the pedestal assembly 200 which stands on its base 204. The pedestal has a top dielectric puck 202 and a lower heater plate 308. Lift pins 322 are placed near the periphery of the dielectric puck in a position that will be below a wafer, when a wafer is electrostatically attached to the puck. The lift pins lift the wafer off of the dielectric puck after a process has been completed. The gas plug 208 is also present in the center of the dielectric puck.

The top surface of the dielectric puck is divided into three different step zones 502, 504, 506. The zones are concentric so that the central zone 502 is encircled and surrounded by an intermediate zone 504 which is encircled and surrounded by a peripheral zone 506. Each zone presents bumps of a different height. In this way, the tops of the bumps are all at the same height. In other words, the surface of the dielectric puck is progressively higher in each step but the flat bottom surface of the wafer is supported level across the bumps. This allows the gas from the gas plug 206 to easily flow outward from the center of the dielectric puck in the space between the wafer and the dielectric puck toward the periphery of the dielectric puck. From the periphery, the gas can escape out the sides of the dielectric puck. This gas may then be removed from the chamber using the exhaust pump or any other desired approach.

The three different step zones are shown as a cross-sectional diagram in FIG. 6. In the central zone 502, the bumps 520 have an initial taller height 526 and the bottom of the dielectric puck 524 around the bumps is at a first depth. In the intermediate zone 504, the bumps 532 are lower, in other words, the tops of the bumps are spaced closer to the bottom of the surface of the dielectric puck 534. The dielectric puck is therefore closer to the wafer and the height 536 of the bumps above the puck is decreased. In the peripheral zone 506, the surface of the puck 544 is still higher so that the bumps 542 are shorter, that is they have a lesser height 546. The bottom of the dielectric puck is still closer to the wafer. This restricts flow from the center of the wafer out toward the periphery of the wafer and provides room for the gas to accumulate near the center before flowing outwards and away from the wafer. More heat is absorbed in the gas and convection is improved when the gas flow is restricted from the center to the edge of the wafer pedestal.

The diagram of FIG. 6 is not to scale. Each bump may have a width on the order of 2 mm to 3 mm and the height of each bump may be on the order of a 0.1 mm. The difference in height may be on the order of 0.02 to 0.03 mm or about one tenth to one third of the total height of the bumps. The size of the bumps and the number of bumps may be adapted to suit different implementations.

The gas may be any of a variety of different gases including Argon which are suitable for conducting heat between the wafer and the dielectric puck. In one example, the bumps are not only taller but are also smaller in diameter. This reduction in diameter is shown in the cross-sectional diagram of FIG. 6 as a reduction in cross-sectional width. While only three steps are shown, a central step, an intermediate step and peripheral step, more or fewer steps may be used to reduce flow and to encourage a radial flow pattern of the gas from the center to the periphery of the wafer. Alternatively, the backside gas flow system may be used without any steps in the dielectric puck.

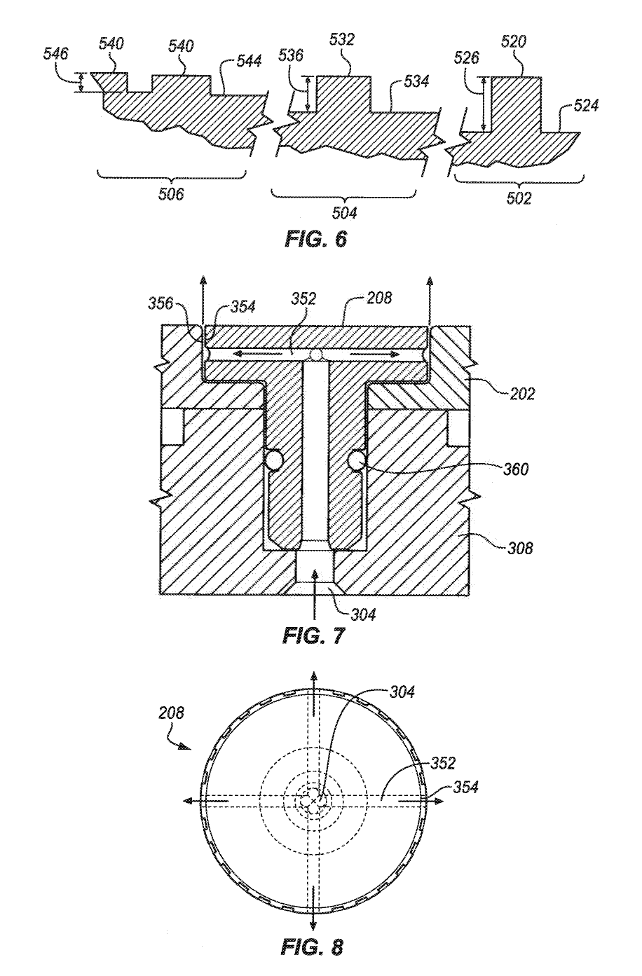

FIG. 7 is a cross-sectional side view diagram of the gas plug 208 as described herein. The gas plug guides the flow of the backside gas into the space between the wafer and the puck to increase the uniformity of the heat transfer between the puck and the wafer. The backside gas is released against the backside of the wafer. The gas flows in through a gas flow channel 304 through the coolant heater plate 308 and the dielectric puck 202. The gas flows from the channel into the plug assembly 208. At one end of the plug assembly, the gas flow changes from a vertical upward flow from the base into the gas plug into a lateral horizontal flow in horizontal flow conduits 352. From these horizontal flow conduits, the gas flows to the edge of the plug 354 and through passageways 356 up and away from the gas plug and toward the wafer backside.

The gas plug is shown as having a spring clip 360 to hold the gas plug in position in the heater plate. This allows the gas plug to be secured in the lower heater plate rather than the upper dielectric puck. The heater plate is typically fabricated from a metal with a high heat conduction such as aluminum. This provides a strong surface to support the gas plug. The dielectric puck is typically constructed of a ceramic material for high heat resistance and for a dielectric characteristic to electrostatically equip the wafer. This allows the elastomeric plug to easily conform to the shape of a hole that has been machined into the ceramic without having the wear from the spring 360 wearing against the ceramic with changes in temperature and pressure.

FIG. 8 provides a top plan view of the gas plug 208 with interior features in dotted line. The central gas flow conduit 304 comes up the center of the chamber of the gas plug. The gas is then directed laterally into the horizontal conduits 352 to extend outwards. In the illustrated embodiment the gas flows in four different directions which are orthogonal or separated by 90°, however, the number of lateral conduits and directions may be modified to suit any particular implementation. In addition, the lateral conduits are not necessarily horizontal but may be angled in any of a variety of different ways to achieve the desired gas flow characteristics.

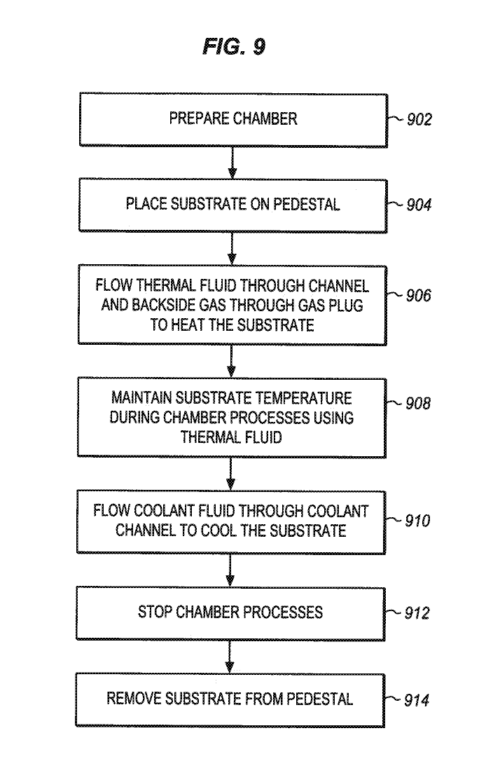

FIG. 9 is a process flow diagram of operating the pedestal in a processing chamber. The pedestal may be used in a wide range of different processing chambers and may also be used for processes that are not performed in processing chambers. The pedestal may be used to hold a variety of different types of substrates, including semiconducting and micromechanical substrates, such as silicon wafers.

At 902 a process chamber is prepared for a fabrication process, such as PECVD. The preparation will depend on the particular process and may include evacuating and cleaning the chamber, adding a gas or chemical environment to the chamber and driving the chamber to a particular temperature.

At 904 a substrate, such as a silicon wafer, or any other substrate is placed on the top surface of the pedestal. As described herein, the wafer may be placed over an array dielectric bumps formed on the top surface or dielectric puck of the pedestal assembly. This may be done using a robot or any other means and is done inside the prepared chamber. Alternatively, depending on the nature of the chamber, the substrate may be attached outside the chamber and then the pedestal and substrate may be moved into the chamber.

At 906 a thermal fluid is pumped through a coolant channel of the pedestal assembly to heat the substrate. This may be done using a pump of a heat exchanger or some other device to force flow through the coolant channel. At the same time, the backside gas is pumped through the gas plug to the backside of the wafer to cause heat convection between the substrate and the pedestal. When the substrate has reached an intended temperature, then the processing chamber is operated by applying energy to the substrate. A plasma process, for example, applies RF energy and chemical reaction energy to the substrate. This heats the substrate. Other processes may heat the substrate in different ways depending on the nature of the process.

At 908 the temperature of the substrate is maintained during substrate processing using the thermal fluid. The thermal fluid is flowed through the coolant channel of the pedestal assembly to cool or heat the substrate as needed. By cooling the fluid in the heat exchanger instead of heating the fluid, the fluid acts to cool the substrate and counter the effects of the process. The fluid may be alternately heated and cooled based on a measured temperature of the coolant or the measured temperature of one or more other parts of the system which may include the fluid to maintain a desired temperature for the substrate.

At 910 the thermal fluid is cooled at the heat exchanger and pumped through the coolant channels of the pedestal assembly to cool the substrate. At 910 the processing chamber operation is stopped and at 912 the substrate is removed from the top surface of the pedestal. Typically, this is done by activating the lift pins to lift the wafer off the pedestal and then a gripper on a robot arm grips the edges of the wafer. The wafer may then be moved to another process chamber or another processing station.

Using the particular mechanical construction described herein, the coolant flows through coolant channels that are open on the top surface of a heater plate so that coolant flowing in the coolant channels is in physical contact with the dielectric puck. This improves heat conduction between the fluid and the puck. The heater plate may also be made of a thermally conductive material so that it also conducts heat to the puck.

Heat conduction between the puck and the substrate may be improved using a back side gas that is pumped through a gas outlet of the dielectric puck to provide gas into a space between the puck top surface and the substrate to conduct heat between the substrate and the puck.

While the example of FIG. 9 is presented in the context of operating a processing chamber and supporting the substrate on a pedestal within a chamber, the invention is not so limited. The pedestal may be used outside the chamber. The coolant fluid allows the temperature of the substrate to be precisely controlled in a wide variety of different circumstances and processes.

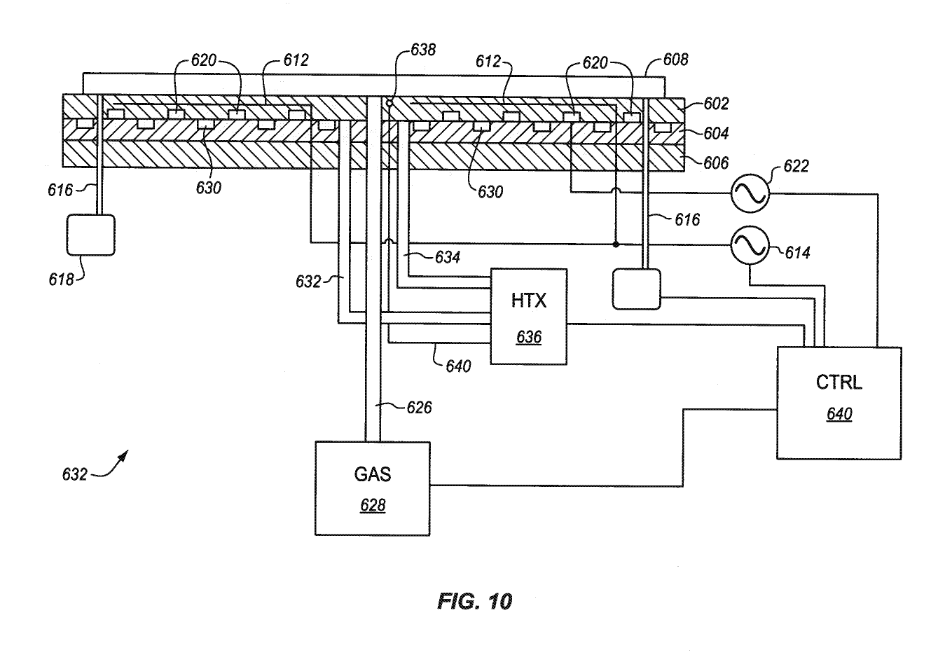

FIG. 10 is a cross-sectional diagram of a substrate support assembly in the form of an electrostatic chuck (ESC) according to alternative embodiments of the present invention. The ESC 632 is formed from three plates 602, 604, 606. An upper or top plate 602 carries electrostatic electrodes 612 to electrostatically attach a substrate 608, such as a silicon wafer to the ESC. The top plate also includes optional resistive heater elements 620 to heat the wafer. The heater elements may be used together with a thermal fluid in coolant channels to produce higher temperatures than the thermal fluid alone.

The top plate 602is attached to a coolant plate 604 which has coolant channels 630. In this example, the coolant channels are open at the top. This allows the channels to be easily machined into the coolant plate and allows for thermal conduction between a thermal fluid in the coolant channel and the top plate. The top plate and the coolant plate are supported by a strong metal backing or base plate 606 for support. The three plates may be cast and machine from aluminum or another material that has good thermal conductivity and is able to withstand the chemical and thermal conditions of a processing chamber. For the ESC the top plate may be coated with or made from a dielectric material to maintain an electrostatic charge to hole the wafer 608 in place.

The ESC is controlled by a controller 640 that is connected to a drive voltage 614 to control the charge applied and maintained for the electrostatic electrodes 612. The controller is connected to a drive current 622 to control the power applied to the optional heater elements 620. The controller is also coupled to a heat exchanger 636 to control the flow rate and temperature of the thermal fluid that is pumped through the coolant channels 630. The heat exchanger is coupled to a supply side line 632 that feeds temperature adjusted coolant to the coolant channels of the coolant plate and to a return line 634 that receives thermal fluid from the ESC and returns it to the heat exchanger 636 to be heated or cooled and supplied back to the supply line. The heat exchanger has a fluid heating system and a fluid cooling system similar to that described in the context of FIG. 1.

The controller further optionally connects to a gas supply 628 to control the flow of a backside gas through a backside gas channel 626 to the back side of the wafer. The backside gas improves heat convection between the wafer 608 and the ESC 632. temperature information from a thermal sensor 638 in the

The ESC 632 further optionally includes one or more thermal sensors 638 in the top plate 602, in a coolant channel 630 or in any other desired locations. The thermal sensor as shown is coupled to the heat exchanger to provide information about the temperature of the wafer 608 or a component that has a temperature that is related to the wafer temperature, such as the top plate. The heat exchanger uses this information to control the temperature of the coolant fluid. The heat exchanger may also provide the temperature information to the controller 640 or the temperature sensor may be connected directly to the controller instead of or in addition to being connected to the heat exchanger.

The ESC also has lift pins 616 and lift pin drive motors 618 to drive the lift pins upwards and release the wafer 608 from the surface 602 of the ESC. The number, position, and operation of the lift pins may be adapted to suit different applications of the ESC and different types of ESC's. The ESC of FIG. 10 is provided as an example. The principles of the present invention may be adapted to a variety of different substrate supports for which a controlled temperature is desired. The ESC and the pedestal described herein may have more or fewer features, depending on the particular implementation.

As described herein a heat exchanger is coupled to a substrate support assembly. The substrate support assembly has a top surface to carry the substrate and fluid channels through which the thermal fluid or coolant flows. The thermal fluid both heats and cools the substrate support and therefore indirectly the substrate. The substrate, as mentioned above, may of many different types. It may be a single wafer of silicon, glass, or some other material or it may have one or more layers. The substrate may also be one that has already had many processing operation applied so that in addition to the substrate there are build-up layers, semiconductor layers, optical layers, or micro-machined layers, for example.

The substrate support can also take different forms. A wafer pedestal and an electrostatic chuck are described and illustrated, however, other devices that carry or support a substrate in a processing chamber may be used with the fluid-based thermal control described herein. A substrate support assembly refers simply to an article for supporting a substrate that has more than one part, such as a top surface to carry the substrate and fluid channels to control the temperature. In the illustrated examples, the substrate support assemblies are formed of two or three plates that are fastened together, but a substrate support may also be made from a single integral piece of material that has been drilled, machined, or built up to have the structures described herein.

It is to be understood that the above description is intended to be illustrative, and not restrictive. For example, while flow diagrams in the figures show a particular order of operations performed by certain embodiments of the invention, it should be understood that such order is not required (e.g., alternative embodiments may perform the operations in a different order, combine certain operations, overlap certain operations, etc.). Furthermore, many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration within the spirit and scope of the appended claims. The scope of the invention should, therefore, be determined with reference to the appended claims, along with the full scope of equivalents to which such claims are entitled.

What is claimed is:

1. A thermally controlled substrate support comprising:
a top surface to support a substrate, the top surface being thermally coupled to substrate;
a thermal fluid channel thermally coupled to the top surface to carry a thermal fluid, the thermal fluid to draw heat from and provide heat to the top surface; and
a heat exchanger to supply thermal fluid to the thermal fluid channel, the heat exchanger alternately heating and cooling the thermal fluid to adjust the substrate temperature.

2. The substrate support of claim 1, further comprising a temperature sensor thermally coupled to the top surface and coupled to the heat exchanger to provide a sensed temperature to the heat exchanger and wherein the heat exchanger controls the heating and cooling of the thermal fluid based at least in part on the sensed temperature.

3. The substrate support of claim 2, wherein the temperature sensor is coupled to the heat exchanger through a controller having a processor to control the heat exchanger.

4. The substrate support of claim 2, wherein the temperature sensor is positioned in the top surface to sense a temperature of the top surface of the substrate support.

5. The substrate support of claim 1, wherein the top surface is circular to carry a circular substrate having a circular area and wherein the thermal fluid channel extends in arcs that are coextensive with the area of the substrate.

6. The substrate support of claim 5, wherein the thermal fluid channel extends in a spiral pattern from the center of the pedestal to the edge of the pedestal.

7. The substrate support of claim 1, further comprising dielectric puck including the top surface and a heater plate attached to the dielectric puck opposite the top surface and wherein the thermal fluid channels are in the heater plate.

8. The substrate support of claim 7, wherein the thermal fluid channels are open on a side of the heater plate facing the dielectric puck so that thermal fluid flowing in the thermal fluid channels is in physical contact with the dielectric puck.

9. The substrate support of claim 1, wherein the top surface comprises a plurality of bumps to support the substrate, the bumps supporting the substrate at a distance from the top surface determined by the bumps and wherein the top surface comprises concentric zones, each zone being a different distance from the substrate, wherein the top surface is farthest from the substrate in a central zone having the tallest bumps and wherein the top surface is closest to the substrate in a peripheral zone having the shortest bumps.

10. The substrate support of claim 9, wherein the central zone includes a gas outlet to provide gas into a space between the top surface and the bumps to conduct heat between the substrate and the top surface, the space being defined by the height of the bumps in the central zone.

11. The substrate support of claim 10, wherein the gas outlet has a plurality of lateral vents to release gas in a direction across the top surface.

12. The substrate support of claim 9, further comprising an intermediate zone having an intermediate distance from the substrate and bumps with an intermediate height.

13. A method comprising:
placing a substrate on a support assembly within a processing chamber;
flowing a thermal fluid through a thermal fluid channel of the support assembly to heat the substrate;
operating a processing chamber by applying energy to the substrate;
flowing the thermal fluid through the thermal fluid channel of the support assembly to cool the substrate;
stopping the processing chamber operation; and
detaching the substrate from the support assembly.

14. The method of claim 13, wherein flowing the thermal fluid comprises flowing the thermal fluid through thermal fluid channels that are open on a top surface of a heater plate so that thermal fluid flowing in the thermal fluid channels is in physical contact with a dielectric puck of the support assembly, the dielectric puck including a top surface upon which the substrate is placed.

15. The method of claim 13, further comprising measuring the temperature of the thermal fluid and controlling the temperature of the thermal fluid through a heat exchanger to alternately heat and cool the thermal fluid depending on the temperature measurement.

16. The method of claim 13, further comprising pumping a backside gas through a gas outlet of the support assembly to provide gas into a space between the support assembly and the back side of the substrate to convect heat between the substrate and the support assembly.

17. A substrate processing system comprising:
a processing chamber to apply a process to a substrate;
a thermally controlled support assembly within the chamber, the support assembly including a dielectric top surface to carry the substrate, the top surface being thermally coupled to the substrate, and the support assembly having a thermal fluid channel thermally coupled to the top surface to carry a thermal fluid, the thermal fluid to draw heat from and provide heat to the support assembly top surface;
a heat exchanger to drive the thermal fluid through the thermal fluid channel and to control the temperature of the thermal fluid and thereby the temperature of the substrate.

18. The system of claim 17, further comprising a temperature sensor attached to the support assembly to measure a temperature that is an indication of the temperature of the substrate, the temperature sensor being coupled to the heat exchanger for use in controlling the temperature of the thermal fluid.

19. The system of claim 17, wherein the support assembly comprises a lower heater plate formed of a conductive metal and a dielectric puck including the top surface, the dielectric puck being formed of a ceramic material and attached to the lower heater plate.

20. The system of claim 17, further comprising a backside gas source to pump a backside gas to the support assembly and through a gas outlet of the support assembly into a space between the top surface and the substrate to conduct heat between the substrate and the top surface.
